(19) United States
(12) Patent Application Publication
(10) Pub. No.: US 2026/0015727 A1
(43) Pub. Date: Jan. 15, 2026

(54) THROTTLE VALVE POSITION ENDPOINT CONTROL WITHIN A DEPOSITION PROCESS

(71) Applicant: Applied Materials, Inc., Santa Clara, CA (US)

(72) Inventors: Yantao GAO, Shanghai (CN); Lianjuan REN, Tianjin (CN); Yongxin ZHU, Beijing (CN)

(21) Appl. No.: 19/120,899

(22) PCT Filed: Jul. 11, 2024
(86) PCT No.: PCT/CN2024/104967

§ 371 Date: Apr. 14, 2025

(51) Int. Cl. C23C 16/52; C23C 16/44; C23C 16/505; H01J 37/32

(52) U.S. Cl. CPC C23C 16/52; C23C 16/4408; C23C 16/4412; C23C 16/505; H01J 37/32449; H01J 37/32834; H01J 37/32908

(57) ABSTRACT

Technologies related to throttle valve (TV) endpoint control of a deposition process are described. A deposition process may be initialized. During the deposition process, a throttle valve stabilization step may be performed. This throttle valve stabilization step may include determining a throttle valve position for a throttle valve coupled to an exhaust port of the processing chamber and determining whether the throttle valve position satisfies a throttle valve position criterion. The deposition process may proceed to a next step of the deposition process and depositing a film on a substrate in response to determining that the throttle valve position satisfies the throttle valve position criterion.

### BACKGROUND

In the semiconductor industry, the deposition of films on substrates is generally performed following process recipes that direct operations of a processing chamber. These films can be composed of various materials, including metals, dielectrics, and semiconductors, and are used to form the active and passive layers of integrated circuits. The thickness of these films is generally dependent on the process recipe followed by the processing chamber. A processing chamber may follow different process recipes at different times.

### BRIEF SUMMARY

Embodiments of the present disclosure relate to throttle valve endpoint control of a deposition process. In one embodiment, a method initiates a deposition process in a deposition chamber. A throttle valve stabilization step is performed that includes determining a throttle valve position for a throttle valve coupled to an exhaust port of the processing chamber and determining whether the throttle valve position satisfies a throttle valve position criterion. Responsive to determining that the throttle valve position satisfies the throttle valve position criterion, the processing logic proceeds to a next step of the deposition process and deposits a film on the substrate.

In another embodiment, a device includes memory having or storing a process recipe for a deposition process and one or more processors to control a deposition process based on the process recipe. The one or more processors may initiate a deposition process in the processing chamber and perform a throttle valve stabilization step that includes determining a throttle valve position for a throttle valve coupled to an exhaust port of the processing chamber and determining whether the throttle valve position satisfies a throttle valve position criterion. Responsive to determining that the throttle valve position satisfies the throttle valve position criterion, the one or more processors may proceed to a next step of the deposition process and deposits a film on the substrate.

In another embodiment, a system includes a processing chamber, gas lines coupled to the processing chamber including at least a first gas line carrying an inert gas and a second gas line carrying a process gas, a throttle valve coupled to an exhaust port of the processing chamber, and a controller to control the system. The controller may initiate flow of one or more gasses carried by the gas lines into the processing chamber and perform a throttle valve stabilization step that includes determining a throttle valve position for the throttle valve and determining whether the throttle valve position satisfies a throttle valve position criterion. Responsive to determining that the throttle valve position satisfies the throttle valve position criterion, the controller may perform a pressure stabilization step at which a pressure of the processing chamber is stabilized and thereafter cause the processing chamber to deposit a film on a substrate.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a sectional view of a processing chamber, according to one embodiment.

FIG. 2 is a diagram illustrating a semiconductor processing system, according to one embodiment.

FIG. 3A is a graph illustrating the first wafer effect after switching process recipes, according to one embodiment.

FIG. 3B is a graph illustrating first wafer effect variance depending on the switched process recipe, according to one embodiment.

FIG. 4A is a portion of a conventional deposition process that includes a gas initialization step, a pressure stabilization step, and a deposition step, according to one embodiment.

FIG. 4B is a portion of a deposition process that includes a throttle valve (TV) stabilization step before the deposition step of a deposition process, according to one embodiment.

FIG. 5 is a graph illustrating throttle valve (TV) positioning throughout a deposition process, according to one embodiment.

FIG. 6 is a flowchart illustrating a method of selecting and updating throttle valve (TV) position criterion, according to one embodiment.

FIG. 7 illustrates a method of performing a deposition process, according to one embodiment.

### DETAILED DESCRIPTION

Technologies related to throttle valve (TV) endpoint control of a deposition process are described. In semiconductor manufacturing, maintaining consistency across all substrates (e.g., wafers) in a production run helps to achieve high yield and cost efficiency. The “first wafer effect” poses a significant challenge in this regard, particularly when a processing chamber switches between different process recipes (e.g., film deposition recipes). The first wafer effect can be particularly significant when the process recipes are sensitive to chamber temperature environment. In general, this first wafer effect results in the first few wafers of a batch exhibiting suboptimal qualities, such as non-confirming film thickness, uneven film thickness (poor uniformity), poor material properties, and deviations in electrical characteristics. These suboptimal qualities generally lead to waste and operational cost mitigation strategies, such as a dummying process. The dummying process involves running one or several “dummy” wafers through the deposition equipment prior to the processing of actual product wafers. These dummy wafers are used to monitor the stabilization of the deposition environment within the processing chamber and ensure that parameters of the processing chamber are properly adjusted to the new process recipe. However, the dummying process can have certain drawbacks, such as increasing an overall cycle time of the manufacturing process (e.g., reducing up-time of the processing chamber), waste generation, or risk of contamination while switching between production and dummying wafers.

Aspects and embodiments of the present disclosure solve the above-described problems and deficiencies and others by providing a deposition process with throttle valve (TV) endpoint control. The deposition process may include a TV stabilization step that expires after a position of the TV meets a criterion corresponding to a current process recipe. The TV stabilization step may include determining a position of the TV and determining whether the TV position satisfies a throttle valve position criterion. The TV may be coupled to an exhaust port of the processing chamber. Responsive to determining that the throttle valve position satisfies the throttle valve position criterion, a next step of the deposition process may proceed, and a film may be deposited on the substrate. Introduction of the throttle valve stabilization step to a process recipe enables stabilization of a chamber environment prior to an etch or deposition step and reduces or eliminates the first wafer effect commonly seen in process recipes. Aspects and embodiments of the present disclosure reduce waste generation by reducing or eliminating the use of dummy wafers when switching between process recipes that result it different film thicknesses. Aspects and embodiments of the present disclosure provide a deposition process that, when switching process recipes, causes the processing chamber to wait until the TV is in a position to provide a gas pressure corresponding to the new process recipe.

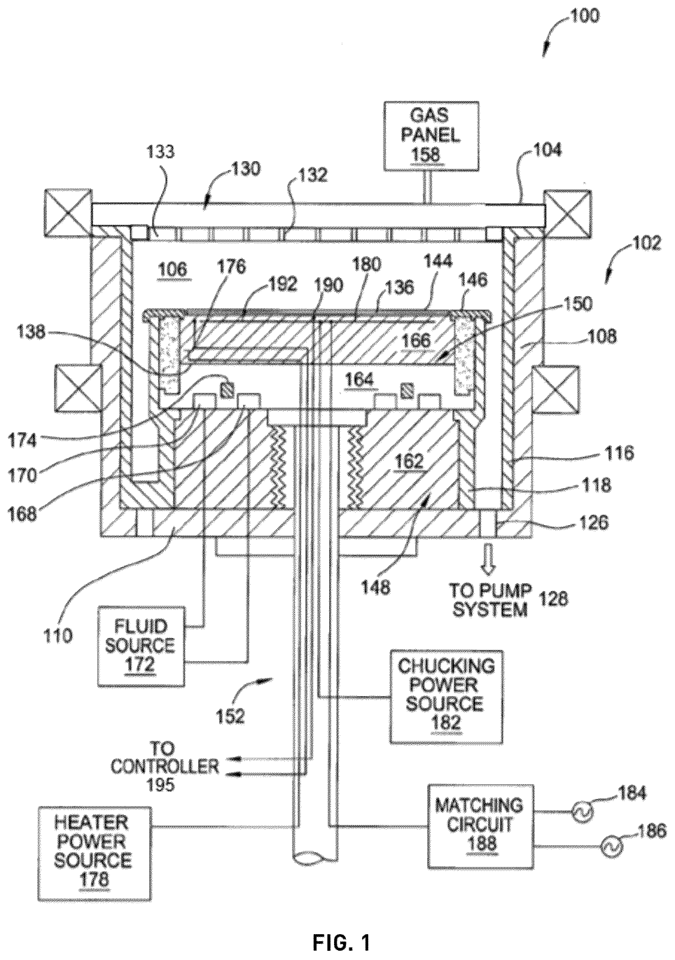

FIG. 1 is a sectional view of a processing chamber 100 (e.g., a semiconductor processing chamber), in accordance with one embodiment. The processing chamber 100 may be used for processes in which a corrosive plasma environment is provided. For example, the processing chamber 100 may be a chamber for a plasma etcher or plasma etch reactor, a plasma cleaner, and so forth. In alternative embodiments other processing chambers may be used, which may or may not be exposed to a corrosive plasma environment. Some examples of process chambers include a chemical vapor deposition (CVD) chamber, a physical vapor deposition (PVD) chamber, an ion assisted deposition (IAD) chamber, an atomic later deposition (ALD) chamber, an etch chamber, an oxidation chamber, an ion implanter, and other types of processing chambers.

In one embodiment, the processing chamber 100 includes a chamber body 102 and a showerhead 130 that enclose an interior volume 106. Alternatively, the showerhead 130 may be replaced by a lid and a nozzle in some embodiments. The chamber body 102 may be fabricated from aluminum, stainless steel, or other suitable material. The chamber body 102 generally includes sidewalls 108 and a bottom 110. One or more of the showerhead 130 (or lid and/or nozzle), sidewalls 108 and/or bottom 110 may include a one or more apertures.

An outer liner 116 may be disposed adjacent the sidewalls 108 to protect the chamber body 102. The outer liner 116 may be fabricated to include one or more apertures. In one embodiment, the outer liner 116 is fabricated from aluminum oxide.

An exhaust port 126 may be defined in the chamber body 102 and may couple the interior volume 106 to a pump system 128. The pump system 128 may include one or more pumps and throttle valves (TVs) utilized to evacuate and regulate the pressure of the interior volume 106 of the processing chamber 100. In some embodiments, the one or more TVs may be coupled between the exhaust port 126 and the one or more pumps of the pump system 128. Throttle valve position may be measured, and throttle valve position may be a process parameter associated with one or more steps of a process recipe in embodiments.

The showerhead 130 may be supported on the sidewall 108 of the chamber body 102. The showerhead 130 (or lid) may be opened to allow access to the interior volume 106 of the processing chamber 100 and may provide a seal for the processing chamber 100 while closed. A gas panel 158 may be coupled to the processing chamber 100 to provide process and/or cleaning gases to the interior volume 106 through the showerhead 130 or lid and nozzle (e.g., through apertures of the showerhead or lid and nozzle). One or more gas lines may carry these process and/or cleaning gases to the gas panel 158 and/or to the showerhead 130. The showerhead 130 may be used for processing chambers used for dielectric etch (etching of dielectric materials). The showerhead 130 includes a gas distribution plate (GDP) 133 having multiple gas delivery apertures 132 throughout the GDP 133. The showerhead 130 may include the GDP 133 bonded to an aluminum base or an anodized aluminum base. The GDP 133 may be made from Si or SiC, or may be a ceramic such as Y₂O₃, Al₂O₃, YAG, and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound composed of Y₄Al₂O₉ and a solid-solution of Y₂O₃—ZrO₂. The nozzle may also be a ceramic, such as Y₂O₃, YAG, or the ceramic compound composed of Y₄Al₂O₉ and a solid-solution of Y₂O₃—ZrO₂. The lid, base of showerhead 130, GDP 133 and/or nozzle may be coated with a ceramic layer, which may be composed of one or more of any of the ceramic compositions described herein. The ceramic layer may be a plasma sprayed layer, a physical vapor deposition (PVD) deposited layer, an ion assisted deposition (IAD) deposited layer, or other type of layer. In one embodiment, the ceramic layer may have been coated onto the chamber component prior to formation of apertures. It is noted that any of the chamber components described herein may have ceramic layers or other types of layers, such as anodized aluminum layers.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases). The substrate support assembly 148 is disposed in the interior volume 106 of the processing chamber 100 below the showerhead 130 or lid. The substrate support assembly 148 holds the substrate 144 during processing. The substrate support assembly may be moved into several different positions based on where the processing chamber 100 is within a process recipe. For example, during a film deposition step of a process recipe, the substrate support assembly 148 may place the substrate in a location within the interior volume 106 that is suitable for film deposition (e.g., “move to process” position). If the processing chamber 100 has completed a process recipe cycle, the substrate support assembly 148 may remove the substrate from the interior volume 106 (e.g., “move to release” position). A ring 146 (e.g., a single ring) may cover a portion of the electrostatic chuck 150 and may protect the covered portion from exposure to plasma during processing. The ring 146 may be silicon or quartz in one embodiment.

An inner liner 118 may be coated on the periphery of the substrate support assembly 148. The inner liner 118 may be a halogen-containing gas resistant material such as those discussed with reference to the outer liner 116. In one embodiment, the inner liner 118 may be fabricated from the same materials of the outer liner 116. Additionally, the inner liner 118 may be coated with a ceramic layer and/or have one or more apertures passing through.

In one embodiment, the substrate support assembly 148 includes a mounting plate 162 supporting a pedestal 152, and an electrostatic chuck 150. The electrostatic chuck 150 further includes a thermally conductive base 164 and an electrostatic puck 166 bonded to the thermally conductive base by a bond 138, which may be a silicone bond in one embodiment. An upper surface of the electrostatic puck 166 is covered by the ceramic layer 136 in the illustrated embodiment. In one embodiment, the ceramic layer 136 is disposed on the upper surface of the electrostatic puck 166. In another embodiment, the ceramic layer 136 is disposed on the entire exposed surface of the electrostatic chuck 150 including the outer and side periphery of the thermally conductive base 164 and the electrostatic puck 166. The mounting plate 162 is coupled to the bottom 110 of the chamber body 102 and includes passages for routing utilities (e.g., fluids, power lines, sensor leads, etc.) to the thermally conductive base 164 and the electrostatic puck 166.

The thermally conductive base 164 and/or electrostatic puck 166 may include one or more optional embedded heating elements 176, embedded thermal isolators 174 and/or conduits 168, 170 to control a lateral temperature profile of the substrate support assembly 148. The conduits 168, 170 may be fluidly coupled to a fluid source 172 that circulates a temperature regulating fluid through the conduits 168, 170. The embedded thermal isolator 174 may be disposed between the conduits 168, 170 in one embodiment. The heating element 176 is regulated by a heater power source 178. The conduits 168, 170 and heating element 176 may be utilized to control the temperature of the thermally conductive base 164, which may be used for heating and/or cooling the electrostatic puck 166 and a substrate 144 (e.g., a wafer) being processed. The temperature of the electrostatic puck 166 and the thermally conductive base 164 may be monitored using a plurality of temperature sensors 190, 192, which may be monitored using a controller 195.

The electrostatic puck 166 may further include multiple gas passages or apertures such as grooves, mesas, and other surface features, which may be formed in an upper surface of the electrostatic puck 166 and/or the ceramic layer 136. The gas passages may be fluidly coupled to a source of a heat transfer (or backside) gas such as helium via apertures drilled in the electrostatic puck 166. In operation, the backside gas may be provided at controlled pressure into the gas passages to enhance the heat transfer between the electrostatic puck 166 and the substrate 144. The electrostatic puck 166 includes at least one clamping electrode 180 controlled by a chucking power source 182. The clamping electrode 180 (or other electrode disposed in the electrostatic puck 166 or conductive base 164) may further be coupled to one or more RF power sources 184, 186 through a matching circuit 188 for maintaining a plasma formed from process and/or other gases within the processing chamber 100. The power sources 184, 186 are generally capable of producing an RF signal having a frequency from about 50 kHz to about 3 GHz, with a power output of up to about 10,000 Watts.

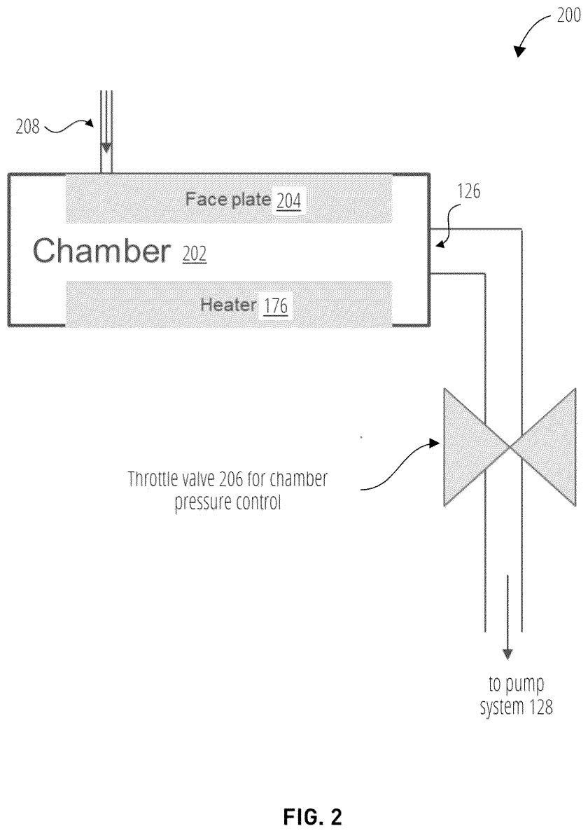

FIG. 2 is a diagram illustrating a simplified processing system 200, according to one embodiment. The processing system 200 may include some or all of the features of the processing chamber 100 described above with respect to FIG. 1. The processing system 200 may include a processing chamber 202 with a face plate 204, a heating element 176, and an exhaust port 126 (as described above with respect to FIG. 1). A TV 206 may be coupled to the exhaust port 126 and lead to the pump system 128. Gas lines 208 carrying inert (e.g., non-reactive) and process (e.g., reactive) gases may be coupled to the processing chamber 202. Tetraethyl orthosilicate (TEOS) may be one of these process gases in some embodiments. In at least one embodiment, the processing system 200 is a plasma enhanced chemical vapor deposition (PECVD) chamber that performs PECVD processes according to different recipes. These recipes may call for film thicknesses varying from 10 angstroms (Å) to over 14K Å in embodiments.

To calibrate the processing system 200 for different process recipes, a controller (not illustrated) may cause characteristics within the processing chamber 202 to change based on the ideal gas law, which may be represented by the following equation (1):

$$ideal gas law$$

$$V = \frac{nRT}{P} , \qquad equation ( 1 )$$

In equation (1), P represents a pressure of gas within the processing chamber 202, V represents the volume of the gas, n represents a number of moles of the gas, T represents a temperature (in kelvin, K) of the gas, and R represents the ideal universal gas constant (8.314 J/mol·K). In at least one embodiment, the controller may at least change a position of the TV 206 such that the pressure (P) within the processing chamber 202 is either reduced or increased, which affects the overall volume of the gas within the processing chamber 202. So, by opening (e.g., increasing an angle) or closing (e.g., decreasing an angle) of the TV 206, the controller is capable of increasing or decreasing the volume of the gas within the chamber, which effects how quickly or effectively a film is deposited on a substrate within the processing chamber 202 during a film deposition process. In general, increasing the pressure of process gases typically increases the deposition rate. This is because more reactive species are generated in the plasma and transported to the substrate surface, leading to a faster buildup of material. However, excessively high gas flows can lead to other issues like poor adhesion or excessive particulate formation due to turbulence within the gas stream. Lower gas rates generally decrease the deposition rate, as fewer reactant molecules are available to participate in the chemical reactions that form the film. Lower flow rates can lead to more uniform and controlled film growth. However, a lower deposition rate decreases productivity of the chamber. In many applications, the deposition process is on a timer. For example, in the scenario where the processing chamber 202 is a PECVD chamber, the controller may apply the RF signal to an internal portion of the chamber (i.e., to begin the film deposition process, a deposition step of the deposition process) for a set period of time based on the current process recipe. Thus, to achieve a target film thickness corresponding to the process recipe, the deposition rate should be calibrated to allow deposited film to reach the target film thickness within that period of time. By adjusting the position of the TV 206, the controller may be capable of calibrating the deposition rate to the duration of the deposition step of the current process recipe.

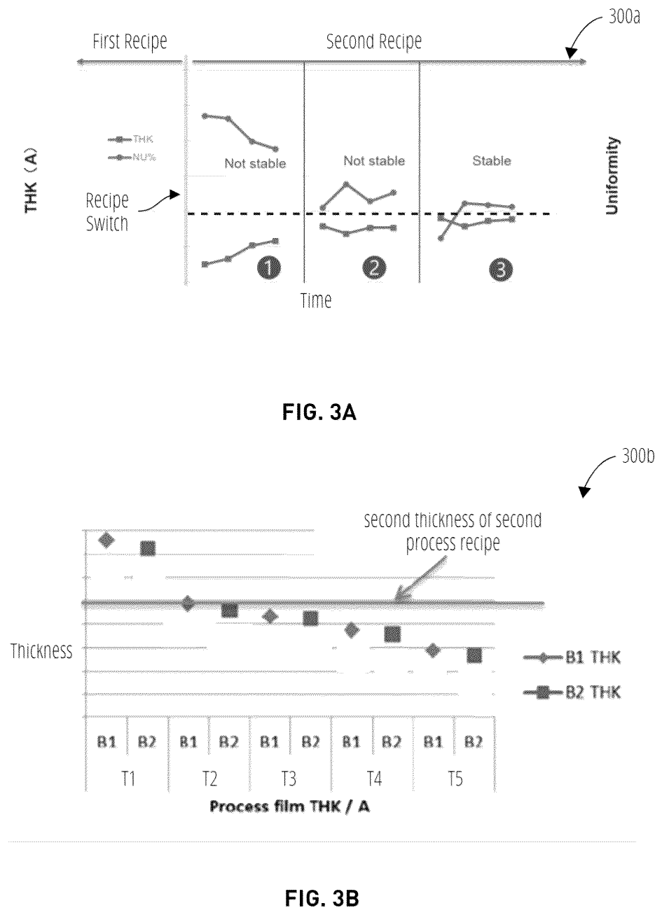

FIG. 3A is a graph 300a illustrating the first wafer effect after switching process recipes, according to one embodiment. In particular, the graph 300a depicts switching from a first process recipe for a first thickness of film deposition to a second process recipe for a second lesser thickness of film deposition. Conventionally, process run(s) occurring directly after the process recipe switch are likely to have non-conforming film thicknesses and/or film thickness non-uniformity. So, conventionally, process runs with dummy substrates (e.g., a dummying process) are used to measure the film thickness until the processing chamber begins to deposit a uniform, conforming thickness of film. For this exemplary graph 300a, consider that a conforming film thickness will be a target thickness T1 and a uniform film thickness will vary by less than about 2-5% (e.g., less than 3%). In the graph 300a, two batch process runs are performed after switching process recipes. The products (e.g., substrate with a deposited film) of the first two batch process runs, as illustrated, have non-conforming film thicknesses. The squares represent the thickness of film deposition for each process run, and the circles represent a percentage of uniformity of the film thickness. The first two batch process runs may have unstable uniformity as well. A common method of calculating uniformity is described below in equation (2):

$$σ = \sqrt{\frac{\sum {( {x}_{i} - μ )}^{2}}{N}}$$

Here, σ is film uniformity, N is a total number of measurement points, xᵢ is a thickness value for the ith measurement, and μ is the average thickness value of total measurement points.

In contrast, the present disclosure describes herein a deposition process that causes the processing chamber to refrain from depositing film on a substrate until a position of the throttle valve (TV) meets criterion corresponding to the new process recipe. By doing so, this deposition process reduces or eliminates the dummying process by avoiding having multiple process runs producing suboptimal products with non-conforming and/or non-uniform film deposition.

FIG. 3B is a graph 300b illustrating first wafer effect variance depending on the switched process recipe, according to one embodiment. In particular, the graph 300b depicts switching from a various first process recipes having first film thicknesses T1-T5. These first film thicknesses T1-T5 may range in thickness from 0 Å to 14K Å or more. A selected process recipe switches from this first process recipe to a second process recipe having a second film thickness that is different than the first film thickness. Within the graph 300b, diamonds and squares represent thicknesses of different types of chemical vapor deposition (CVD) or plasma enhanced CVD (PECVD). For this exemplary graph 300b, consider that a conforming film thickness of the second process recipe is any film thickness within a range of thicknesses that includes the second film thickness. As can be seen, the first wafer effect can significantly vary depending on the prescribed film thickness (T1, T2, T3, T4, or T5) of the previous process recipe. This variation makes determining an amount of time between (i) switching from the first process recipe to the second process recipe and (ii) an internal environment of the process chamber stabilizing enough to generate products with film thicknesses conforming to the second process recipe. However, as described herein, using a position of the TV as an endpoint control value to determine when to first deposit film on a substrate can significantly reduce the first wafer effect.

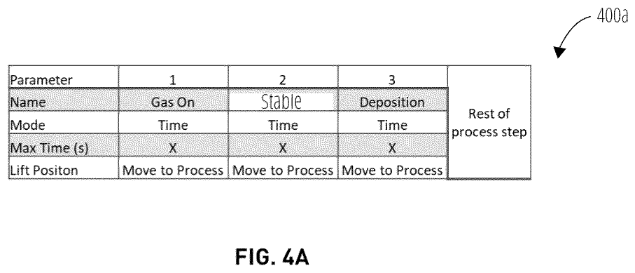

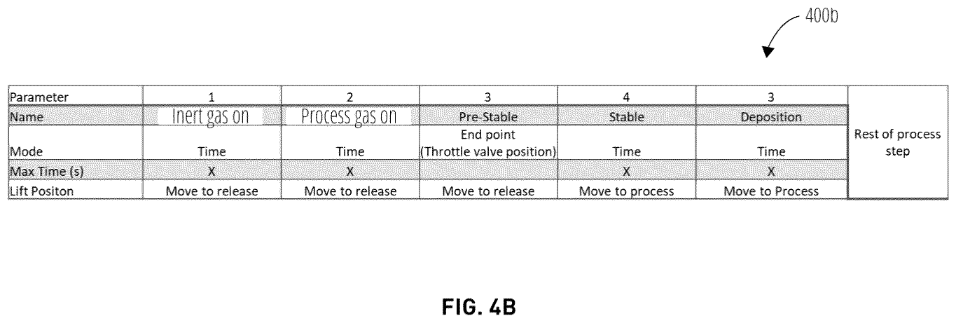

FIG. 4A is a portion of a conventional deposition process 400a that includes a gas initialization (Gas On) step, a pressure stabilization (Stable) step, and a deposition step, according to one embodiment. During the gas initialization step, one or more inert gases may be introduced to the processing chamber. During the pressure stabilization step, one or more process gases may be introduced to the processing chamber. These one or more process gases may include tetraethyl orthosilicate (TEOS). In other embodiments, other process gases may be used, such as Silane (SiH₄), Ammonia (NH₃), Tungsten Hexafluoride (WF₆), Trimethylaluminum (TMA), Diborane (B₂H₆), Phosphine (PH₃), or Hydrogen Chloride (HCl). During the deposition step, a film may be deposited on a substrate. In embodiments where the processing chamber is a PECVD, a radio frequency (RF) signal may be introduced to the processing chamber during the deposition process. The conventional deposition process may include one more steps before or after the conventional deposition process 500a, such as an RF purge step (if the processing chamber is a PECVD or otherwise uses RF signals during the deposition step), a gas purge step (purging of one or more inert or process gasses), a lift step (e.g., causing a substrate support assembly to remove the substrate from the processing chamber), or a pump step (e.g., a step to remove all inert or process gases from the processing chamber). Each step included in the conventional deposition process 400a (at least of the portion illustrated) may be time-controlled. For example, the gas initialization step, the pressure stabilization step, and the deposition step may each expire based on time limits. Additionally, a substrate support assembly (e.g., lift) may place substrate in a position to be processed (e.g., a position where, upon initializing the deposition process, film is deposited on the substrate).

FIG. 4B is a portion of a deposition process 400b that includes a throttle valve (TV) stabilization step (e.g., Pre-Stable) before the deposition step of a deposition process, according to one embodiment. The deposition process 400b may be controlled by processing logic that may comprise hardware (e.g., circuitry, dedicated logic, programmable logic, microcode, etc.), software (e.g., instructions run on a processing device to perform hardware simulation), firmware, or a combination thereof. This processing logic may cause the deposition process 400b to be performed by a substrate processing system including a processing chamber, one or more gas lines, and one or more throttle valves. In some embodiments, the deposition process 400b may be controlled by a controller, such as the controller described above with respect to FIGS. 1-2. The deposition process 400b can be controlled at least partially by other devices, such as a cloud database or processor having one or more processing devices.

In some embodiments, this TV stabilization step may be before a pressure stabilization step, but after one or more process gases have been introduced to the processing chamber. Thus, in at least one embodiment, the TV stabilization step occurs while one or more inert gases and one or more process gases are flowing through the processing chamber.

One or more steps of the deposition process 400b may be time-controlled. For these steps, the deposition process 400b is set to run for a specific duration. This duration may be based on historical data predetermined through experimental data and process optimization techniques. Other steps, such as the TV stabilization step, may involve endpoint control. These endpoint control steps may involve real-time monitoring and control to determine when criterion for certain parameters is achieved. An example criterion can be a TV position or range of positions. This monitoring can be done through various methods involving different types of sensors, such as a throttle position sensor (e.g., a potentiometer-based sensor), optical emission spectroscopy, interferometry, or mass spectrometry. Endpoint control can be particularly useful in process steps that can may have a variable duration. As an example, the TV stabilization step may be an endpoint control step that expires only after the TV position to meet certain TV position criterion (e.g., be within a target range of positions) before the deposition process 400b moves onto a pressure stabilization step. This TV position criterion may be determined based on previous process run(s) of a processing chamber.

The operational parameters and control methods described above for one TV can be effectively applied to multiple throttle valves if multiple throttle valves are coupled to the exhaust port of the same processing chamber. This can help ensure uniform control across all TVs, facilitating consistent process conditions and outcomes throughout the chamber.

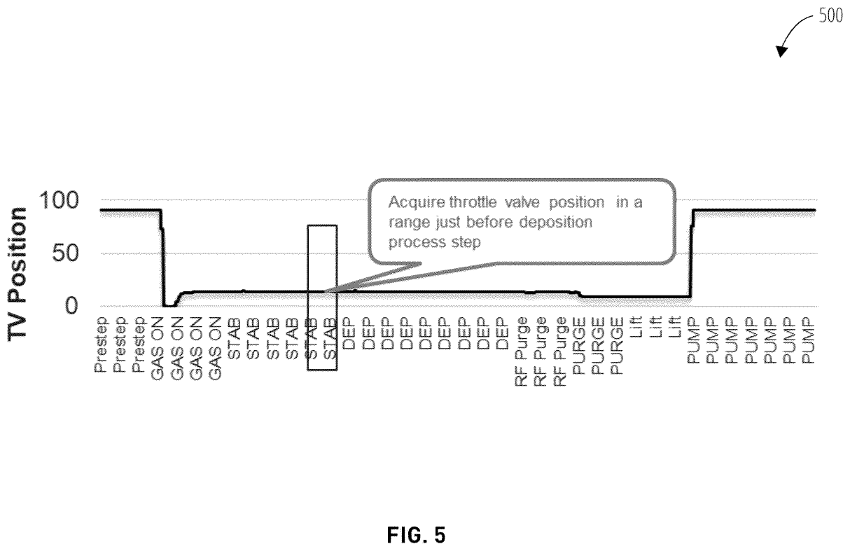

FIG. 5 is a graph 500 illustrating throttle valve (TV) positioning throughout a deposition process, according to one embodiment. The x-axis represents sequential steps of the deposition process, and the y-axis represents the position of the TV. The position of the TV may be represented by an angle, with 90 degrees meaning that the TV is completely open and 0 degrees meaning that the TV is completely closed. The TV may be completely open before and after an iteration of the deposition process (e.g., Prestep and PUMP, as illustrated). The TV may be completely closed while one or more inert or process gases are introduced to the processing chamber (e.g., at the beginning of GAS ON, as illustrated). During the deposition process, the TV may regulate the pressure of gases within the processing chamber. While not illustrated, the present disclosure introduces a new step between initializing the gas and a pressure stabilization step (e.g., between GAS ON and STAB, as illustrated) that expires after a position of the TV meets a TV position criterion. This TV position criterion may be a certain angle or range of angles that correspond to a current process recipe of the deposition process. This criterion may be dependent on one or more historical process runs of the deposition process (e.g., historical iterations of the deposition process) corresponding to the same process recipe. These historical process runs may have been performed using the same processing chamber as a current process run.

In at least some embodiments, the position of the TV may be sampled one or more times right before a deposition step of the deposition step begins. The position of the TV may be sampled during the pressure stabilization step. If the deposition process results in products that conform to the process recipe, these sampled position(s) may be used to generate criterion for subsequent process runs using the same process recipe. These sampled position(s) may be used to generate a target position of the TV or a target range of positions of the TV for subsequent process runs using the same process recipe. In at least one embodiment, target positions or ranges of positions may each be stored in reference to a different process recipe. In these embodiments, once the process recipe is switched (e.g., from a first process recipe for first thickness of film deposition to a second process recipe for second thickness of film deposition), the TV stabilization step may refer to a target position or target range of positions corresponding to the new process recipe (e.g., the second process recipe).

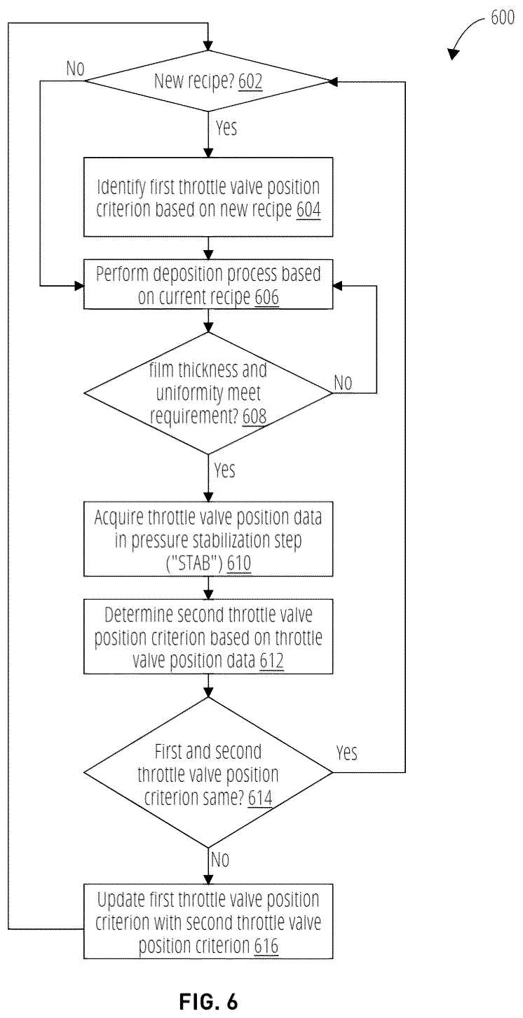

FIG. 6 is a flowchart illustrating a method 600 of selecting and updating throttle valve (TV) position criterion, according to one embodiment. The method 600 may be performed by processing logic that may comprise hardware (e.g., circuitry, dedicated logic, programmable logic, microcode, etc.), software (e.g., instructions run on a processing device to perform hardware simulation), firmware, or a combination thereof. This processing logic control operations of a substrate processing system including a processing chamber, one or more gas lines, one or more throttle valves, and an exhaust port. In some embodiments, the method 600 may be performed by a controller, such as the controller described above with respect to FIGS. 1-2. The method 600 can be controlled at least partially by other devices, such as a cloud database or processor having one or more processing devices.

In deposition processes within a processing chamber, the environment temperature within the processing chamber can vary significantly from one run to another. This variability in temperature can be attributed to several factors, such as including changes in ambient conditions, variations in the cooling and heating systems' efficiency, or different levels of thermal load from the deposition process itself. For example, the amount of power supplied to a source material for evaporation or sputtering can introduce significant thermal fluctuations. These temperature variations can critically affect the physical properties of the deposited films, such as their uniformity, crystallinity, and adhesion. Given the sensitive nature of film deposition to temperature variations, additional control capabilities may facilitate the production of products (e.g., substrate with deposited film) that satisfy specification requirements (e.g., quality criteria). The present disclosure provides an additional control capability by (i) introducing a throttle valve stabilization step with endpoint control to a deposition process, and (ii) providing a method (e.g., method 600) of maintaining this endpoint control based on current processing chamber conditions.

In at least one embodiment, the processing logic may maintain a group of TV position criterion corresponding to different process recipes. Each of these different process recipes may call for different film thicknesses to be deposited on a substrate. For example, the processing logic may maintain TV position criterion for at least a first process recipe calling (e.g., having, corresponding to) for a first thickness and a second process recipe calling for a second thickness different from the first thickness. The first and second thicknesses may be selected from a group including, but not limited to, 300 Å, 600 Å, 3K (3000) Å, 6K Å, 10K Å, 12K Å, or 14K Å, or some other thickness. This group of thicknesses may include any film thickness suitable for a product.

At decision block 602, the processing logic determines whether a new process recipe has been selected. In other words, the processing logic determines whether the process recipe for the deposition recipe has switched from the first process recipe corresponding to the first thickness to a second process recipe corresponding to the second thickness. If a new process recipe has been selected, the processing logic identifies and retrieves a first TV position criterion based on the new recipe at block 604. This first TV position criterion may be part of the group of TV position criterion that is maintained by the processing logic. The first TV position criterion may be an angle or range of angles of the TV that corresponds to the process recipe before the deposition process proceeds to a pressure stabilization step or to a film deposition step. If the process recipe has not switched, the processing logic may not identify the first TV position criterion may not be identified or acquired as the process recipe has not switched. In this scenario, the processing logic may perform the deposition process based on the non-switched process recipe and its corresponding TV position criterion at block 606. Otherwise, if the process recipe switched, the processing logic may perform the deposition process based on the new process recipe and its corresponding first TV position criterion at block 606.

The decision block 602 may be an optional feature of the method 600. In at least one embodiment, the processing logic may simply identify and retrieve the TV position criterion based on a current process recipe. In other words, the processing logic may identify and retrieve a TV position criterion based on whatever process recipe is currently being followed by the deposition process.

At decision block 608, the processing logic may determine whether film thickness and uniformity of a product generated during block 606 meets specification requirements. These specification requirements may be based on functional performance, device reliability, standards and regulations, or the like. Several measurement techniques may be employed to assess the uniformity and thickness of thin films, each suitable for different types of materials and required precision levels. Some non-limiting examples of measuring film uniformity and thickness may include ellipsometry, profilometry, X-ray reflectivity, or spectroscopic reflectometry. Ellipsometry is a widely used optical technique that measures film thickness by analyzing the change in polarization as light reflects off the film surface. It's particularly effective for very thin films, offering high precision. Profilometry, both contact and non-contact types, may be used to physically scans the surface of the film to determine its topography, which provides data on thickness variations (i.e., uniformity) across the film. Contact profilometry involves a stylus that moves across the film, while non-contact versions use optical methods like laser scanning. X-ray reflectivity may be used primarily for thin films, providing not only thickness information but also density and interface quality by measuring the intensity of X-rays reflected at different angles. For films with uniformity requirements over larger areas, spectroscopic reflectometry may be useful, as it measures the intensity of light reflected at different wavelengths to infer film thickness across a broader area. The product not meeting film thickness and uniformity specification requirements indicates that the first TV position criterion is not accurate, and the position of the TV should be adjusted for subsequent process runs of the deposition process using the selected recipe. As such, if the product does not meet film thickness and uniformity specification requirements, the method 600 may wait until a next product is generated using the current process recipe before determining whether film thickness and uniformity of the next product meets specification requirements, as denoted by the arrow back to block 606. However, in some embodiments, if the product does not meet film thickness and uniformity specification requirements, the method 600 may terminate and wait until a next iteration of the deposition process is initiated (e.g., wait for a next process run) at decision block 602 or block 604.

If film thickness and uniformity of the product generated at block 606 satisfies specification requirements, the processing logic may acquire TV position data that corresponds to the pressure stabilization step at block 610. The TV position data to be acquired may be depicted in FIG. 6. In at least one embodiment, the TV position data that is acquired may correspond to a time shortly before (or directly before) the film deposition step of the deposition process is to be initialized. In another embodiment, the acquired TV position data may correspond to the film deposition step of the deposition process. This TV position data may include one TV position data point representing one angle of the TV at a first time, or multiple TV position data points each representing an angle of the TV at multiple times.

At block 612, a second TV position criterion is generated based on the TV position data acquired at block 610. The second TV position may be a range of angles or positions that includes each data point within the TV position data, an average of the data point(s) of the TV position data, or some other combination of the data point(s) of the TV position data. In at least one embodiment, the first TV position criterion is generated using historical TV position data corresponding to a historical process run of the selected process recipe.

At decision block 614, the second TV position criterion is compared to the first TV position criterion. If they are substantially similar (e.g., within 20% of each other, within 10% of each other, within 5% of each other, within 1% of each other), then the first TV position criterion is not updated with the second TV position criterion, and the first TV position criterion is retained to use during a subsequent process run of the deposition process using the current process recipe. If the first and second TV position criterions are substantially different from each other, then the second TV position criterion supplants the first TV position criterion at block 616, and the second TV position criterion is retained to use during the subsequent process run of the deposition process using the current process recipe.

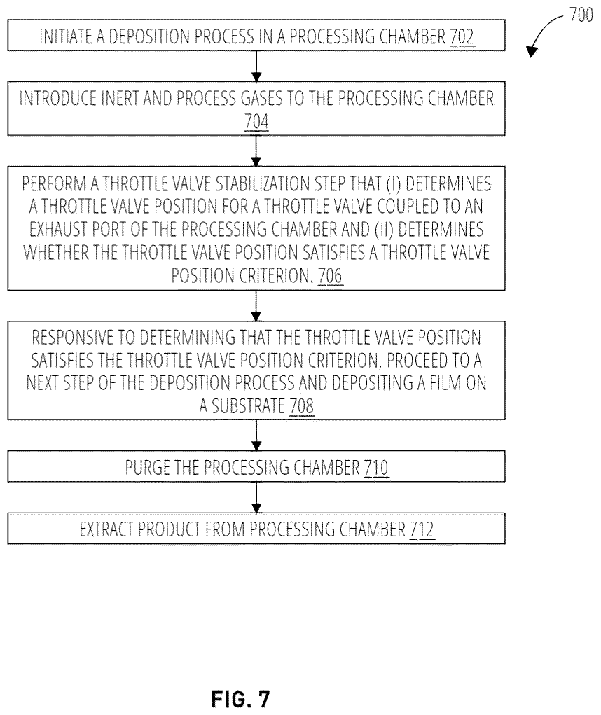

FIG. 7 illustrates a method 700 of performing a deposition process, according to one embodiment. The method 700 may be performed by processing logic that may comprise hardware (e.g., circuitry, dedicated logic, programmable logic, microcode, etc.), software (e.g., instructions run on a processing device to perform hardware simulation), firmware, or a combination thereof. This processing logic control operations of a substrate processing system including a processing chamber, one or more gas lines, one or more throttle valves, and an exhaust port. In some embodiments, the method 700 may be performed by a controller, such as the controller described above with respect to FIGS. 1-2. The method 700 can be controlled at least partially by other devices, such as a cloud database or processor having one or more processing devices.

At block 702, the processing logic may initiate a deposition process in a processing chamber. This initialization may include placing a substrate into the processing chamber, sealing the processing chamber, and evacuating the processing chamber to a low pressure using a vacuum pump. The processing chamber may be evacuated to remove air and other unwanted gases from the processing chamber.

At block 704, the processing logic may introduce one or more inert or process gases to the processing chamber, such that these inert or process gases are flowing through the processing chamber while the throttle valve stabilization step is performed. Tetraethyl orthosilicate (TEOS) may be one of these process gases. Other process gases that can be used include, but are not limited to, Silane (SiH₄), Ammonia (NH₃), Tungsten Hexafluoride (WF₆), Trimethylaluminum (TMA), Diborane (B₂H₆), Phosphine (PH₃), and Hydrogen Chloride (HCl). Examples of inert gas(es) that may be introduced to the processing chamber include argon, nitrogen, helium, and neon, which are utilized to stabilize the reaction environment and purge the deposition chamber.

At block 706, the processing logic may perform a throttle valve stabilization step. During this throttle valve stabilization step, the processing logic may determine a throttle valve position for a throttle valve coupled to an exhaust port of the processing chamber. The processing logic may also determine whether the throttle valve position satisfies a throttle valve position criterion during this throttle valve stabilization step. This throttle value position criterion may be dependent on a previous deposition process that was performed by the processing chamber. The throttle value position criterion may be based on throttle valve position data that is acquired shortly before (or directly before) a historical film deposition step of a historical deposition process. In another embodiment, this throttle valve position data may correspond to the historical film deposition step. This throttle valve position data may include one throttle valve position data point representing one historical position (e.g., angle) of the throttle valve at a first time, or multiple throttle valve position data points each representing a historical position of the throttle valve at different times.

In some embodiments, the throttle valve position criterion may include a throttle valve angle range that corresponds to an average of historical throttle valve angles that are associated with one or more process runs that resulted in products that satisfied one or more quality criteria. This quality criteria may be specification requirements related to film thickness and film uniformity of the product. This angle range may have a minimum acceptable throttle valve position and a maximum acceptable throttle valve position. These maximum and minimum throttle valve positions may each correspond to a maximum and minimum historical throttle valve position value (e.g., angle value), respectively. In another embodiment, these maximum and minimum throttle valve positions may be selected based on an average of the historical throttle valve positions. In at least one embodiment, the throttle valve angle range may have a minimum acceptable throttle valve position and a maximum acceptable throttle valve position that are separated by up to 2 degrees.

At block 708, the processing logic may proceed to a next step of the deposition process and depositing a film on a substrate. Proceeding to this next step may be responsive to determining that the throttle valve position satisfies the throttle valve position criterion. In one embodiment, this next step may be a pressure stabilization step. In this embodiment, the film may be deposited on the substrate after the pressure stabilization step expires. In another embodiment, the next step may be a film deposition step. The pressure stabilization step may facilitate consistent and uniform film deposition. During the pressure stabilization step, after processes gas(es) are introduced into the processing chamber, flow rates are maintained (and sometimes slightly adjusted) to achieve a stable and uniform gas composition throughout the processing chamber. A stable and uniform gas composition allows for consistent and more precise film growth during the deposition step. During the deposition step, in the context of a PECVD process, process gas(es) are ionized by radio frequency (RF) power to form a plasma. This plasma enhances the chemical reactions necessary for film growth at lower temperatures compared to standard CVD techniques. The energized species from the plasma interact with the surface of the substrate, where they decompose and form a thin film layer. The deposition step, in context of a CVD process, includes heating process gas(es) until atoms or molecules of the process gas(es) decompose and deposit on the substrate.

At block 710, the processing logic may cause the processing chamber to be purged after the deposition step has expired. This purge may include a gas purge and a radio frequency (RF) purge. A gas purge in a deposition process involves flushing the processing chamber with an inert gas (e.g., nitrogen or argon) to remove residual gases and by-products from previous reactions. A gas purge helps ensure that no unwanted chemicals are left in the processing chamber, which could contaminate the next deposition cycle. During a gas purge, the inert gas may be introduced at a controlled flow rate to effectively sweep the processing chamber, displacing and carrying away contaminants. After sufficient gas purging, the processing chamber is typically vented to atmospheric pressure or vacuumed to prepare for the next deposition step or for substrate removal. An RF purge in deposition processes may utilize radio frequency power to create a plasma from an inert gas, such as argon or nitrogen. This plasma enhances the cleaning process by energetically interacting with and effectively breaking down residual particles and chemical residues on surfaces of the processing chamber. The reactive species generated by the plasma can provide a more thorough cleaning compared to a typical inert gas purge. However, in some embodiments, both a gas purge and an RF purge may be utilized to clean the processing chamber of contaminations such as residual particles and chemical residues. After the RF purge, the processing chamber may be cleared of the plasma and any volatile byproducts are removed.

At block 712, a product may be extracted from the processing chamber. In at least one embodiment, the processing logic may cause the product to be extracted from the chamber. In another embodiment, the product may be extracted by a user. The product may be a substrate with a deposited film. This product may be related any number of industries, such as, but not limited to, semiconductor, display, or photovoltaic industries. In the context of the semiconductor industry, the deposition process described herein may produce a product with a dielectric film such as silicon dioxide (SiO₂) or silicon nitride (Si₃N₄), which are generally associated with insulating layers, passivation layers, and masking in integrated circuits. In the context of the display industry, the deposition process described herein may produce a product with thin-film transistors (TFTs) and barrier layers that are part of organic light emitting diode (OLED) and liquid crystal display (LCD) screens. In the context of the photovoltaic industry, the deposition process described here may produce a product with anti-reflective coatings and silicon nitride layers (e.g., on solar cells) that provide enhanced light absorption and electrical passivation.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present invention. Thus, the specific details set forth are merely exemplary. Particular embodiments may vary from these exemplary details and still be contemplated to be within the scope of the present disclosure.

Reference throughout this specification to “one embodiment” or “an embodiment” indicates that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of embodiments of the invention should, therefore, be determined with reference to the appended claims, along with the full scope of equivalents to which such claims are entitled.

What is claimed is:

1. A method comprising:
initiating a deposition process in a processing chamber;
performing a throttle valve stabilization step comprising:
determining a throttle valve position for a throttle valve coupled to an exhaust port of the processing chamber; and
determining whether the throttle valve position satisfies a throttle valve position criterion; and
responsive to determining that the throttle valve position satisfies the throttle valve position criterion, proceeding to a next step of the deposition process and depositing a film on a substrate.

2. The method of claim 1, wherein proceeding to the next step comprises performing a pressure stabilization step at which a pressure within the processing chamber is stabilized, wherein the film is deposited on the substrate after the pressure stabilization step.

3. The method of claim 1, further comprising performing the following prior to determining the throttle valve position:
initiating flows of one or more gases into the processing chamber.

4. The method of claim 3, wherein the one or more gases comprise an inert gas and a process gas.

5. The method of claim 4, wherein the process gas comprises tetraethyl orthosilicate (TEOS).

6. The method of claim 1, wherein the deposition process is performed based on a process recipe associated with a first film thickness, and wherein the throttle valve position criterion is dependent on a historical deposition process that was performed by the processing chamber based on the process recipe.

7. The method of claim 1, wherein the throttle valve position criterion comprises a throttle valve angle range that corresponds to an average of historical throttle valve angles that associated with one or more process runs that resulted in products that satisfied one or more quality criteria.

8. The method of claim 7, wherein the throttle valve angle range comprises a minimum acceptable throttle valve position and a maximum acceptable throttle valve position that is separated from the minimum acceptable throttle valve position by up to 2 degrees.

9. The method of claim 1, wherein the processing chamber is a plasma enhanced chemical vapor deposition (PECVD) chamber, and wherein the deposition process is a PECVD process.

10. A device comprising:
a memory comprising a process recipe for a deposition process; and
one or more processors to control a deposition process based on the process recipe, wherein the one or more processors are to:
initiate a deposition process in a processing chamber;
perform a throttle valve stabilization step comprising:
determining a throttle valve position for a throttle valve coupled to an exhaust port of the processing chamber; and
determine whether the throttle valve position satisfies a throttle valve position criterion; and
responsive to determining that the throttle valve position satisfies the throttle valve position criterion, proceed to a next step of the deposition process and cause the processing chamber to deposit a film on a substrate.

11. The device of claim 10, wherein to proceed to the next step, the one or more processors are to perform a pressure stabilization step at which a pressure within the processing chamber is stabilized, and wherein the film is deposited on the substrate after the pressure stabilization step.

12. The device of claim 10, wherein prior to determining the throttle valve position, the one or more processors are to:
initiate flows of one or more gases into the processing chamber.

13. The device of claim 12, wherein the one or more gases comprise an inert gas and a process gas.

14. The device of claim 13, wherein the process gas comprises tetraethyl orthosilicate (TEOS).

15. The device of claim 10, wherein the deposition process is performed based on a process recipe associated with a first film thickness, and wherein the throttle valve position criterion is dependent on a historical deposition process that was performed by the processing chamber based on the process recipe.

16. The device of claim 10, wherein the throttle valve position criterion comprises a throttle valve angle range that corresponds to an average of historical throttle valve angles that associated with one or more process runs that resulted in products that satisfied one or more quality criteria.

17. The device of claim 16, wherein the throttle valve angle range comprises a minimum acceptable throttle valve position and a maximum acceptable throttle valve position that is separated from the minimum acceptable throttle valve position by up to 2 degrees.

18. The device of claim 10, wherein the processing chamber is a plasma enhanced chemical vapor deposition (PECVD) chamber, and wherein the deposition process is a PECVD process.

19. A system comprising:
a processing chamber;
a plurality of gas lines coupled to the processing chamber comprising a first gas line carrying an inert gas and a second gas line carrying a process gas;
a throttle valve coupled to an exhaust port of the processing chamber; and
a controller to control the system, wherein the controller is to:
initiate flow of one or more gases carried by the plurality of gas lines into the processing chamber;
perform a throttle valve stabilization step comprising:
determining a throttle valve position for the throttle valve; and
determine whether the throttle valve position satisfies a throttle valve position criterion; and
responsive to determining that the throttle valve position satisfies the throttle valve position criterion:
perform a pressure stabilization step at which a pressure of the processing chamber is stabilized; and
after the pressure stabilization step, cause the processing chamber to deposit a film on a substrate.

20. The system of claim 19, wherein the throttle valve position criterion is dependent on a historical deposition process that was performed by the system.
